(19) United States
(12) Patent Application Publication
(10) Pub. No.: US 2025/0243378 A1
(43) Pub. Date: Jul. 31, 2025

(54) SURFACE LAYER PROTECTION FILM FOR INORGANIC MATERIALS, ETCHING METHOD, AND METHOD FOR PRODUCING INORGANIC MATERIAL THAT HAS ETCHED SURFACE LAYER

(71) Applicant: Daicel Corporation, Osaka-shi, Osaka (JP)

(72) Inventors: Kenji MOCHIDA, Tokyo (JP); Tsubasa MIKI, Tokyo (JP)

(73) Assignee: Daicel Corporation, Osaka-shi, Osaka (JP)

(21) Appl. No.: 18/855,891

(22) PCT Filed: Apr. 10, 2023
(86) PCT No.: PCT/JP2023/014620

§ 371 Date: Oct. 10, 2024

(30) Foreign Application Priority Data
Apr. 14, 2022 (JP) 2022-066881
May 30, 2022 (JP) 2022-087812

(51) Int. Cl. C09D 101/28; H01L 21/311

(52) U.S. Cl. CPC C09D 101/284; H01L 21/31111

(57) ABSTRACT

The present disclosure provides a surface layer protection film for an inorganic materials; an etching method for a surface layer of an inorganic material; and a method for producing an inorganic material having a surface layer that has been etched.

### TECHNICAL FIELD

The present disclosure relates to a surface layer protection film for an inorganic material, an etching method, a method for producing an inorganic material having an etched surface layer, and a method for manufacturing a semiconductor device using the production method. The present disclosure claims the rights of priority from JP 2022-066881 filed in Japan on Apr. 14, 2022 and JP 2022-087812 filed in Japan on May 30, 2022, the contents of which are incorporated herein by reference.

### BACKGROUND ART

A known method for manufacturing a semiconductor element includes: forming a silicon oxide film and a silicon nitride film on a surface of a semiconductor wafer, patterning them into a desired shape, and etching. As the etching method, a wet etching method is known in which the silicon oxide film or the silicon nitride film is etched and removed by an etching liquid such as sulfuric acid, nitric acid, phosphoric acid, or hydrofluoric acid.

Patent Document 1 indicates that a silicon nitride film can be selectively etched, that is, etching selectivity can be enhanced, by carrying out an etching process using a hot phosphoric acid solution while protecting a silicon oxide film using a hot phosphoric acid-resistant material that is selectively chemisorbed to the silicon oxide film.

### CITATION LIST

### Patent Document

Patent Document 1: JP 2013-062278 A

### SUMMARY OF INVENTION

### Technical Problem

However, the silicon oxide film cannot be selectively etched by the method of Patent Document 1. Further, it is difficult to remove the hot phosphoric acid-resistant material that remains after the etching process.

Accordingly, an object of the present disclosure is to provide a surface layer protection film for an inorganic material so that the surface layer protection film exhibits sufficient adhesion during an etching process and is easily removed once the etching process is completed.

Another object of the present disclosure is to provide an etching method for selectively etching an oxide film or a nitride film of an inorganic material.

Yet another object of the present disclosure is to provide a production method for producing an inorganic material having a surface layer that is etched with high precision using the protection film to selectively etch a desired film selected from an oxide film and a nitride film.

Another object of the present disclosure is to provide a method for manufacturing a semiconductor device, the manufacturing method including etching an oxide film or a nitride film on a surface of a semiconductor wafer using the abovementioned production method.

### Solution to Problem

As a result of diligent research to solve the problems described above, the present inventors have discovered the following.

That is:
1. A protection film containing a water-soluble cellulose is excellent in adhesion to the surface layer of an inorganic material and is not detached by an etching process, but can be easily removed by washing with warm water or an alkaline aqueous solution when the protection film is no longer necessary.
2. Of an oxide film and a nitride film of a surface layer of an inorganic material, one can be selectively etched using an aqueous solution containing a water-soluble cellulose before treating the inorganic material having the surface layer including the oxide film and the nitride film with an acidic etching liquid or simultaneously with the acidic etching liquid.
3. When a protection film containing the water-soluble cellulose is provided on an entire surface layer including an oxide film and a nitride film and then treated with an etching liquid that selectively etches the oxide film or the nitride film, the etching selectivity is remarkably improved. For example, when the protection film containing the water-soluble cellulose is treated with an etching liquid that selectively etches the oxide film, the etching rate of the nitride film can be remarkably suppressed without suppressing the etching rate of the oxide film, and as a result, etching selectivity is improved. When the protection film containing the water-soluble cellulose is treated with an etching liquid that selectively etches the nitride film, the etching rate of the oxide film can be remarkably suppressed without suppressing the etching rate of the nitride film, and as a result, etching selectivity is improved.

The present disclosure has been completed based on these findings.

That is, the present disclosure provides a surface layer protection film for an inorganic material, the surface layer protection film containing a water-soluble cellulose.

The present disclosure also provides the surface layer protection film, in which the water-soluble cellulose is a cellulose derivative having a constituent unit represented by Formula (c) or a salt thereof.

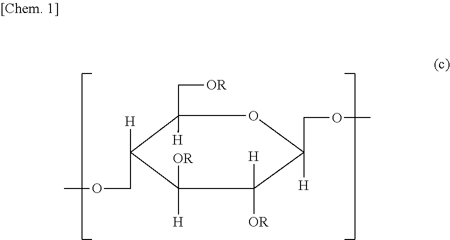

where three R's may be the same or different, and each denotes a hydrogen atom, a hydrocarbon group, or a group in which two or more hydrocarbon groups are bonded through a linking group, and the hydrocarbon group may have a hydroxyl group or a carboxyl group, with proviso that at least one of three R's is a hydrocarbon group or a group in which two or more hydrocarbon groups are bonded through a linking group.

The present disclosure also provides an etching method for an inorganic material, the inorganic material including, on a surface layer thereof, two types of films having different etching rates when etched with an acidic etching liquid, the etching method comprising selectively etching, of the two types of films, the film having the higher etching rate, by:
(A) simultaneously supplying an aqueous solution containing a water-soluble cellulose and an acidic etching liquid to the surface layer; or
(B) supplying an aqueous solution containing a water-soluble cellulose to the surface layer, and then supplying an acidic etching liquid to the surface layer.

The present disclosure also provides a method for producing an inorganic material having an etched surface layer, the method including subjecting an inorganic material having a surface layer including an oxide film and a nitride film to steps 1 and 2 to produce the inorganic material having the etched surface layer, wherein the steps 1 and 2 are:
1: producing a [protection film/surface layer/inorganic material] laminate by laminating the surface layer protection film to the surface layer of the inorganic material having a surface layer including an oxide film and a nitride film; and
2: selectively etching the oxide film or the nitride film of the surface layer by bringing an acidic etching liquid that selectively etches the oxide film or the nitride film into contact with the [protection film/surface layer/inorganic material] laminate.

The present disclosure also provides the production method, in which, in the step 2, an etching selectivity ratio of the oxide film or the nitride film in relation to the other of the oxide film and the nitride film in the selectively etching is 150 or greater.

The present disclosure also provides the production method, in which, in the step 1, the surface layer protection film is laminated by applying an aqueous solution containing a water-soluble cellulose to the surface layer of the inorganic material having a surface layer including an oxide film and a nitride film, and then drying the aqueous solution and the surface layer.

The present disclosure also provides the production method, in which the steps 1 and 2 are followed by the following step 3:
3: washing and removing the remaining protection film with warm water or an alkaline aqueous solution.

The present disclosure also provides a method for manufacturing a semiconductor device, the manufacturing method including etching a surface layer of a semiconductor wafer having a surface layer including an oxide film and a nitride film by the production method described above.

### Advantageous Effects of Invention

A protection film of the present disclosure contains a water-soluble cellulose and therefore adheres well to a surface layer of an inorganic material and does not detach during an etching process. The protection film is unnecessary after completion of the etching process, and in this case, the protection film can be easily removed by washing with warm water or an alkaline aqueous solution.

In an etching method according to an embodiment of the present disclosure, an aqueous solution containing a water-soluble cellulose is used during the wet etching process, and thus, of the two types of films having different etching rates of the surface layer of the inorganic material, the film having the higher etching rate can be selectively etched.

In addition, in a production method according to an embodiment of the present disclosure, it is not necessary to apply the protection film containing the water-soluble cellulose to only the film that is not to be etched among the oxide film and the nitride film of the inorganic material having a surface layer including an oxide film and a nitride film. Instead, the protection film is applied to both the oxide film and the nitride film, and an etching liquid that selectively etches the oxide film or the nitride film is applied, and thereby high etching selectivity can be achieved.

The etching selectivity can be further improved by applying a dried protection film containing a water-soluble cellulose to the surface layer of the inorganic material and then applying the etching liquid.

Therefore, according to the production method of an embodiment of the present disclosure, an inorganic material having a surface layer that has been etched with high precision can be produced.

Moreover, when the oxide film or the nitride film on the surface of a semiconductor wafer is etched using the production method described above, a semiconductor element having a highly precise wiring pattern can be formed, and a high-performance semiconductor device can be manufactured by mounting the semiconductor element.

### DESCRIPTION OF EMBODIMENTS

### Protection Film

A protection film according to an embodiment of the present disclosure is a film having a function of protecting a surface layer of an inorganic material, and contains at least a water-soluble cellulose as a polymer compound. For example, when the surface layer of an inorganic material is to be subjected to processing including cutting (for example, wet etching, organic film detachment, or the like) or thin film formation (for example, thin film formation by plating, chemical vapor deposition, atomic layer deposition, or the like), the protection film is used on the surface layer to protect the portion that is not to be subjected to such processing.

The thickness of the protection film is, for example, from 5 to 200 nm. In this range, from the viewpoint of reducing the etching inhibition of the film to be etched, increasing the etching inhibition of the film not to be etched, and improving the etching selectivity, the thickness of the protection film is preferably from 5 to 100 nm, and particularly preferably from 5 to 30 nm.

The protection film can be formed, for example, by applying an aqueous solution containing a water-soluble cellulose (the aqueous solution contains a water-soluble cellulose and water, and may also contain additional polymer compounds, dispersants, surfactants, and the like described below) to the surface layer of the inorganic material, and then subjecting to a drying treatment as necessary.

The water-soluble cellulose is preferably a cellulose that exhibits solubility in water at a temperature from 0 to 100° C. (more preferably from 20 to 60° C.), and the solubility in water at 20° C. is, for example, 5 wt. % or greater.

Examples of the water-soluble cellulose include cellulose derivatives having a constituent unit represented by Formula (c) below, or salts thereof.

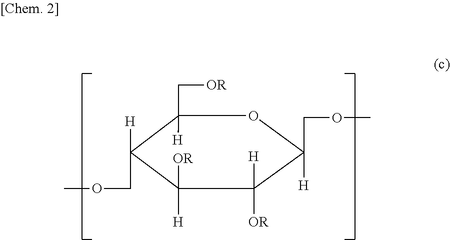

where three R's may be the same or different, and each denotes a hydrogen atom, a hydrocarbon group, or a group in which two or more hydrocarbon groups are bonded through a linking group, the hydrocarbon group may have a hydroxyl group or a carboxyl group, with proviso that at least one of three R's is a hydrocarbon group or a group in which two or more hydrocarbon groups are bonded through a linking group.

The hydrocarbon group is preferably an aliphatic hydrocarbon group, and is particularly preferably a saturated aliphatic hydrocarbon group (=alkyl group).

Examples of the alkyl group include alkyl groups having from 1 to 5 carbons, such as a methyl group, an ethyl group, a propyl group, an isopropyl group, a butyl group, an isobutyl group, a s-butyl group, a t-butyl group, and a pentyl group. Among these, the alkyl group is preferably an alkyl group having from 1 to 3 carbons, and is particularly preferably an alkyl group having 1 or 2 carbons.

The linking group is preferably an ether bond (—O—).

As the group in which two or more hydrocarbon groups are bonded through a linking group, a group represented by the following Formula (r) is preferable. In Formula (r), the bond extending from the left bonds to an oxygen atom.

—R¹—(O—R²)ₙ—X (r)

In Formula (r), R¹ and R² may be the same or different, and each denotes a hydrocarbon group. The hydrocarbon group is preferably an aliphatic hydrocarbon group, and is particularly preferably a saturated aliphatic hydrocarbon group (=alkylene group). The alkylene group is preferably an alkylene group having from 1 to 3 carbons, such as a methylene group, a dimethylene group, a methylmethylene group, a 1-methylethylene group, a 1,1-dimethylmethylene group, or a trimethylene group, and is particularly preferably an alkylene group having 1 or 2 carbons.

In Formula (r) above, X represents a hydroxyl group or a carboxyl group.

In Formula (r) above, n represents the average number of added moles of the (O—R²) group, and is, for example, greater than 0, preferably greater than 0 and 10 or less, and particularly preferably from 1.5 to 3.

The cellulose derivative having the constituent unit represented by Formula (c) above may form a salt. That is, the hydroxyl group or carboxyl group of the cellulose derivative may form a salt with an alkali metal.

Examples of the salt include monovalent metal salts such as alkali metal salts (lithium salts, sodium salts, potassium salts, rubidium salts, cesium salts, and the like), divalent metal salts such as alkaline earth metal salts (calcium salts, magnesium salts, and the like), quaternary ammonium salts, amine salts, substituted amine salts, and double salts thereof. The salt is preferably an alkali metal salt such as a sodium salt or a quaternary ammonium salt.

For example, when the hydroxyl group or the carboxyl group of the cellulose derivative forms a sodium salt, the hydroxyl group (—OH) becomes-ONa, and the carboxyl group (—COOH) becomes —COONa.

The degree of etherification (or the (total) degree of substitution of hydrocarbon groups having a hydroxyl group or a carboxyl group) of the cellulose derivative having the constituent unit represented by the Formula (c) can be selected, for example, from a range of from 0.1 to 3.0. In this range, from the viewpoint of achieving excellent adhesion to the surface layer of the inorganic material and a particularly excellent effect of improving etching selectivity, the degree of etherification is preferably 0.5 or greater, more preferably 0.8 or greater, and particularly preferably 1.0 or greater. The upper limit of the degree of etherification is preferably 2.5, more preferably 2.0, and particularly preferably 1.6. The degree of etherification of the cellulose derivative is an average value of the degrees of etherification (degrees of substitution) of the hydroxyl groups at the 2-, 3-, and 6-positions of the glucose units of the cellulose.

Specific examples of the water-soluble cellulose include methyl cellulose, hydroxyethyl cellulose, hydroxypropyl cellulose, hydroxyethylmethyl cellulose, hydroxypropylmethyl cellulose, carboxymethyl cellulose, carboxyethyl cellulose, and alkali metal salts thereof (for example, sodium carboxymethyl cellulose). A single type of these water-soluble celluloses can be used alone, or two or more types can be used in combination.

The weight-average molecular weight (Mw) of the water-soluble cellulose is, for example, from 0.1×10⁴ to 200×10⁴. From the viewpoint of improving the etching selectivity ratio, the upper limit of the Mw is preferably 100×10⁴, more preferably 80×10⁴, yet even more preferably 50×10⁴, still more preferably 30×10⁴, still even more preferably 20×10⁴, further preferably 15×10⁴, particularly preferably 12×10⁴, most preferably 10×10⁴, and above all, especially preferably 5×10⁴. The lower limit of the Mw is preferably 0.1×10⁴, more preferably 0.3×10⁴, even more preferably 0.5×10⁴, particularly preferably 0.8×10⁴, and most preferably 1×10⁴.

In addition, the water-soluble cellulose may be one in which the hydroxyl groups are crosslinked with each other by a crosslinking agent (for example, glyoxal or the like), but from the viewpoint of improving etching selectivity, the water-soluble cellulose is preferably one having a degree of crosslinking of 0.3% or less (more preferably 0.25% or less, still more preferably 0.2% or less, yet even more preferably 0.1% or less, particularly preferably less than 0.1%, and most preferably 0.05% or less).

From the viewpoint of improving the etching selectivity ratio, the water-soluble cellulose is preferably one having a weight-average molecular weight (Mw) of from 0.1×10⁴ to 20×10⁴ (preferably from 0.5×10⁴ to 15×10⁴, particularly preferably from 0.8×10⁴ to 12×10⁴) and a degree of crosslinking of 0.25% or less (more preferably 0.2% or less, even more preferably 0.1% or less, particularly preferably less than 0.1%, and most preferably 0.05% or less).

The protection film may contain one or more polymer compounds in addition to the water-soluble cellulose, but the proportion of the water-soluble cellulose in the total amount (100 wt. %) of the polymer compounds contained in the protection film is, for example, 50 wt. % or greater, preferably 60 wt. % or greater, more preferably 70 wt. % or greater, even more preferably 80 wt. % or greater, particularly preferably 95 wt. % or greater, and most preferably 99 wt. % or greater.

Examples of the polymer compounds other than the water-soluble cellulose include vinyl-based resins (such as polyvinyl alcohol, polyvinyl acetal, polyvinyl pyrrolidone, polyacrylamide, poly(N-alkylacrylamide), polyallylamine, poly(N-alkylallylamine), partially amidated polyallylamine, poly(diallylamine), allylamine-diallylamine copolymers, polyacrylic acid, polyvinyl alcohol-polyacrylic acid block copolymers, and polyvinyl alcohol-polyacrylate block copolymers), polyalkylene glycols (such as polyethylene glycol), polyglycerin, and water-soluble nylons.

Furthermore, the proportion of the water-soluble cellulose in the total amount (100 wt. %) of the components other than water in the protection film is, for example, 50 wt. % or greater, preferably 60 wt. % or greater, more preferably 70 wt. % or greater, even more preferably 80 wt. % or greater, particularly preferably 95 wt. % or greater, and most preferably 99 wt. % or greater.

The protection film may further contain additional components (such as, for example, a dispersant and a surfactant) besides the polymer compound. The content of the additional components per 100 parts by weight of the water-soluble cellulose is preferably 5 parts by weight or less, more preferably 3 parts by weight or less, and even more preferably 1 part by weight or less.

Examples of the inorganic material include metals (such as gold, silver, copper, platinum, palladium, tin, titanium, molybdenum, tungsten, tantalum, aluminum, and gallium) and semiconductors (such as silicon). The inorganic material can be selected from among these according to the application.

The shape of the inorganic material is not particularly limited, and may be various shapes such as a flat plate shape, a curved plate shape, a columnar shape, a spherical shape, and a disk shape. In addition, the inorganic material may have a complex structure such as grooves or unevenness.

The surface layer of the inorganic material may be composed of the inorganic material itself, or may be composed of an oxide film or a nitride film of the inorganic material. Further, the surface layer may be configured by a combination of these.

The surface layer is preferably one including an oxide film and a nitride film.

For example, when a semiconductor element is to be manufactured, the inorganic material is preferably a semiconductor, and the inorganic material having a surface layer including an oxide film and a nitride film is preferably a silicon substrate (or a silicon wafer) having a surface layer including a silicon oxide (SiO₂) film and a silicon nitride (Si₃N₄) film.

Note that in the surface layer, the region where the oxide film is present and the region where the nitride film is present may be adjacent to each other or may be separated from each other. The oxide film and the nitride film are preferably exposed on the surface of the surface layer to which the protection film is laminated. Moreover, the surface layer including the oxide film and the nitride film may be directly laminated on the inorganic material, or may be laminated to the surface layer with an insulating film, a conductive film for forming a wiring, or the like interposed therebetween.

The protection film does not dissolve in an aqueous solution having a pH of less than 6 and a temperature of less than 40° C. Therefore, if an etching process is carried out using an acidic etching liquid in a state in which the surface layer of the inorganic material is protected by the protection film, the surface layer of the inorganic material is covered during the etching process, and an effect of imparting etching selectivity can be exhibited.

Moreover, the protection film can be easily removed by washing with warm water (for example, ultrapure water having a temperature of 40° C. or greater (preferably from 40 to 85° C.)) or an alkaline aqueous solution (having a pH of, for example, 8 or greater, preferably 10 or greater, and particularly preferably 12 or greater).

### Etching Method

An etching method according to an embodiment of the present disclosure is an etching method for an inorganic material including, on a surface layer thereof, two types of films having different etching rates when etched with an acidic etching liquid. The etching method includes selectively etching, of the two types of films, the film having the higher etching rate, by:
(A) simultaneously supplying an aqueous solution containing a water-soluble cellulose and an acidic etching liquid to the surface layer; or
(B) supplying an aqueous solution containing a water-soluble cellulose to the surface layer, and then supplying an acidic etching liquid to the surface layer.

The two types of films provided on the surface layer of the inorganic material and having different etching rates when etched with an acidic etching liquid (that is, an “easy-to-etch film” having a large (or high) etching rate when etched by the acidic etching liquid and a “hard-to-etch film” having a small (or low) etching rate when etched by the acidic etching liquid) may be composed of, for example, the inorganic material itself, or may be composed of an oxide film or a nitride film of the inorganic material. Further, the two types of films may be configured by a combination of these.

The easy-to-etch film and the hard-to-etch film are films having an etching selectivity ratio [easy-to-etch film/hard-to-etch film] of, for example, 10 or greater (preferably 50 or greater, more preferably 100 or greater, even more preferably 150 or greater, yet even more preferably 200 or greater, still more preferably 250 or greater, further preferably 300 or greater, and particularly preferably 400 or greater) when etched with an acidic etching liquid.

The two types of films are preferably an oxide film and a nitride film, and particularly preferably a silicon oxide (SiO₂) film and a silicon nitride (Si₃N₄) film.

Note that at the surface of the inorganic material, the region where the oxide film is present and the region where the nitride film is present may be adjacent to each other or may be separated from each other.

When an aqueous solution containing a water-soluble cellulose is supplied to the surface layer, the water-soluble cellulose adheres to both the easy-to-etch film and the hard-to-etch film to form a protection film. When this happens, the etching rate of the hard-to-etch film further decreases, whereas a decrease in the etching rate of the easy-to-etch film is suppressed even when the protection film is formed. As a result, the difference in etching rates between the easy-to-etch film and the hard-to-etch film is increased, and the etching selectivity is improved.

That is, the etching method according to an embodiment of the present disclosure increases the etching selectivity of the easy-to-etch film by attaching the water-soluble cellulose to the easy-to-etch film and the hard-to-etch film of the inorganic material surface layer.

In the process (A), the acidic etching liquid and the aqueous solution containing the water-soluble cellulose may be separately supplied to the surface layer of the inorganic material, or a liquid mixture of both the acidic etching liquid and the aqueous solution containing the water-soluble cellulose may be supplied thereto.

The liquid mixture may be prepared by adding the water-soluble cellulose to the acidic etching liquid. The content of the water-soluble cellulose in the liquid mixture is preferably from 0.001 to 3 wt. %, more preferably from 0.005 to 1 wt. %, and even more preferably from 0.01 to 0.5 wt. %.

In the process (B), the aqueous solution containing the water-soluble cellulose may be supplied and dried in advance, and then the acidic etching liquid may be supplied, or the aqueous solution containing the water-soluble cellulose may be supplied followed by the supply of the acidic etching liquid without drying the aqueous solution.

A merit of the process (A) is that the aqueous solution containing the water-soluble cellulose and the acidic etching liquid can be supplied at the same time, and therefore the etching process can be simplified. Furthermore, a merit of the treatment (B) is that a protection film containing a water-soluble cellulose can be formed in advance, and therefore the etching selectivity can be further increased.

The aqueous solution containing the water-soluble cellulose and used in the etching method is the same as that used in the production of the protection film.

The aqueous solution containing the water-soluble cellulose can be prepared by mixing and stirring the water-soluble cellulose, water, and other components as necessary.

The acidic etching liquid is a composition having a function of selectively etching (or dissolving) one of the two types of films (preferably, an oxide film or a nitride film), and contains at least an acidic substance and a solvent. The acidic etching liquid can be selected and used according to the object to be etched.

When it is desired to selectively etch an oxide film (for example, a silicon oxide (SiO₂) film), a composition containing at least one type of acidic substance selected from hydrofluoric acid (HF), ammonium fluoride (NH₄F), acidic ammonium fluoride, ammonium hydrogen fluoride, BHF (a mixture of HF and NH₄F; buffered hydrofluoric acid), DHF (a liquid mixture of HF and H₂O), and the like is preferably used as the acidic etching liquid.

When it is desired to selectively etch a nitride film (for example, a silicon nitride (Si₃N₄) film), a composition containing hot phosphoric acid as the acidic substance is preferably used as the acidic etching liquid.

The solvent used in the acidic etching liquid is preferably water. Moreover, a water-soluble organic solvent (for example, lactone, polyhydric alcohol, etc.) may be used together with water.

The concentration of the acidic substance in the acidic etching liquid is, for example, from 0.05 to 99 wt. %. The concentration of the acidic substance can be appropriately adjusted according to the type of the acidic substance.

When hydrofluoric acid, ammonium fluoride, acidic ammonium fluoride, ammonium hydrogen fluoride, BHF, or DHF is used as the acidic substance, the concentration of the acidic substance in the acidic etching liquid is preferably from 0.05 to 30 wt. %.

When hot phosphoric acid is used as the acidic substance, the concentration of the acidic substance in the acidic etching liquid is preferably from 70 to 99 wt. %, particularly preferably from 72 to 90 wt. %, and most preferably from 75 to 85 wt. %. When the content is 70 wt. % or greater, the generation of particles due to etching problems is less likely to occur, and when the content is 99 wt. % or less, etching selectivity is easily provided.

Examples of a method for supplying the aqueous solution containing the water-soluble cellulose and the acidic etching liquid to the surface layer of the inorganic material include a dipping method and a coating method. The dipping method and the coating method are described in detail later.

### Method for Producing Inorganic Material Having Etched Surface Layer

According to an embodiment of the present disclosure, a method for producing the inorganic material having an etched surface layer (hereinafter, may be referred to as the “etched inorganic material”) is a method in which an inorganic material having a surface layer including an oxide film and a nitride film is subjected to steps 1 and 2 to produce the inorganic material having the etched surface layer, wherein the steps 1 and 2 are:
step 1: producing a [protection film/surface layer/inorganic material] laminate by laminating a protection film containing a water-soluble cellulose to the surface layer of the inorganic material having a surface layer including an oxide film and a nitride film; and
step 2: selectively etching the oxide film or the nitride film of the surface layer by bringing an acidic etching liquid that selectively etches the oxide film or the nitride film into contact with the [protection film/surface layer/inorganic material] laminate.

The production method according to an embodiment of the present disclosure may include another step in addition to the above steps, and for example, the production method may include the step 3 after the steps 1 and 2:
step 3: washing and removing the remaining protection film with warm water or an alkaline aqueous solution.

### Step 1

In step 1, a [protection film/surface layer/inorganic material] laminate (that is, a laminate having a laminated structure of “a protection film/a surface layer/an inorganic material”) is produced by laminating a protection film containing a water-soluble cellulose to the surface layer of the inorganic material having a surface layer including an oxide film and a nitride film.

The protection film can be produced, for example, by forming a coating film of an aqueous solution containing a water-soluble cellulose (hereinafter, may be referred to as a “protection film-forming solution”) on the surface layer of the inorganic material having a surface layer including an oxide film and a nitride film.

The protection film-forming solution contains at least the water-soluble cellulose described above. The concentration of the water-soluble cellulose is, for example, from 0.001 to 3 wt. %. From the viewpoint of achieving an effect of further improving the etching selectivity, the lower limit of the concentration of the water-soluble cellulose is preferably 0.01 wt. %, more preferably 0.05 wt. %, particularly preferably 0.1 wt. %, most preferably 0.25 wt. %, and especially preferably 0.3 wt. %. From the viewpoint of forming a uniform coating film, the upper limit of the concentration of the water-soluble cellulose is preferably 2 wt. %, particularly preferably 1.5 wt. %, most preferably 1.0 wt. %, and especially preferably 0.8 wt. %.

The protection film-forming solution may contain additional components (for example, another polymer compound, a dispersant, and a surfactant) as necessary, besides the water-soluble cellulose and water. The content of the additional components is, for example, 10 parts by weight or less, preferably 5 parts by weight or less, particularly preferably 3 parts by weight or less, and most preferably 1 part by weight or less, relative to 100 parts by weight of the water-soluble cellulose.

The protection film-forming solution can be prepared by mixing and stirring the water-soluble cellulose, water, and the additional components that are used as necessary.

Examples of methods for forming a coating film from the protection film-forming solution on a surface layer of an inorganic material having the surface layer including an oxide film and a nitride film include the following methods.
[1] A method of immersing an inorganic material having a surface layer including an oxide film and a nitride film in the protection film-forming solution (that is, a dipping method)
[2] A method of applying the protection film-forming solution onto the surface layer of the inorganic material having a surface layer including an oxide film and a nitride film (that is, a coating method)

In the coating method [2], examples of the method for applying the protection film-forming solution onto the surface layer of the inorganic material include spin coating, stamping, dispensing, squeegeeing, spraying, and brush coating. Among these methods, the protection film-forming solution is preferably applied by spin coating from the viewpoint of easily producing a uniform protection film.

A coating film (=coating film containing moisture) produced by the dipping method [1] or the coating method [2] may be used as is as the protection film, but a coating film from which the moisture has been removed is preferably used as the protection film because the adhesion of the protection film to the surface layer of the inorganic material can be improved and the etching selectivity can be further enhanced.

That is, preferably, an aqueous solution containing a water-soluble cellulose is applied to a surface layer of an inorganic material having a surface layer including an oxide film and a nitride film to form a coating film, the resulting coating film is subjected to a drying treatment, and the dried protection film containing the water-soluble cellulose is laminated on the surface layer.

In the case of the dipping method [1], preferably, an inorganic material having a surface layer including an oxide film and a nitride film is immersed in an aqueous solution containing a water-soluble cellulose and then removed, after which the coating film attached to the surface layer is subjected to a drying treatment to form a [protection film/surface layer/inorganic material] laminate having a protection film from which moisture has been removed.

In addition, in the case of the coating method [2], preferably, a [protection film/surface layer/inorganic material] laminate having a protection film from which moisture has been removed is formed by applying an aqueous solution containing a water-soluble cellulose onto a surface layer of an inorganic material having a surface layer including an oxide film and a nitride film and then subjecting the resulting coating film to a drying treatment.

The “dried protection film containing the water-soluble cellulose” and the “protection film from which moisture has been removed” are protection films from which all or some of the moisture has been removed, and the content of the moisture in relation to the total amount of the protection film is, for example, preferably 30 wt. % or less, particularly preferably 15 wt. % or less, and most preferably 5 wt. % or less.

Examples of the drying treatment method include a heat-drying method, a ventilation drying method, a reduced-pressure drying method, and a method of blowing a dry gas (e.g., nitrogen gas).

Moreover, before being subjected to the drying treatment, the protection film may be washed with water. By washing the protection film with water, excess water-soluble cellulose can be removed, and the uniformity of the protection film can be improved.

That is, preferably, an aqueous solution containing a water-soluble cellulose is applied to a surface layer of an inorganic material having a surface layer including an oxide film and a nitride film to form a coating film, the resulting coating film is washed with water and then further subjected to a drying treatment, and the dried protection film containing the water-soluble cellulose is laminated on the surface layer.

In the case of the dipping method [1], a [protection film/surface layer/inorganic material] laminate having a protection film from which moisture has been removed is formed, preferably, by immersing an inorganic material having a surface layer including an oxide film and a nitride film in an aqueous solution containing a water-soluble cellulose and removing the inorganic material from the aqueous solution, and then washing the coating film attached to the surface layer and further subjecting the coating film to a drying treatment.

In addition, in the case of the coating method [2], a [protection film/surface layer/inorganic material] laminate having a protection film from which moisture has been removed is formed, preferably, by applying an aqueous solution containing a water-soluble cellulose onto a surface layer of an inorganic material having the surface layer including an oxide film and a nitride film, washing the resulting coating film with water, and further drying the coating film.

### Step 2

In step 2, selectively etching the oxide film or the nitride film of the surface layer by bringing an acidic etching liquid that selectively etches the oxide film or the nitride film into contact with the [protection film/surface layer/inorganic material] laminate produced in step 1.

Examples of the acidic etching liquid include the same examples described as the acidic etching liquid used in the etching method described above.

Among the above-described acidic etching liquids, the acidic etching liquid that selectively etches the oxide film from among the oxide film and the nitride film is an acidic etching liquid having an etching selectivity ratio [oxide film/nitride film] of, for example, 150 or greater (preferably 200 or greater, particularly preferably 250 or greater, most preferably 300 or greater, and above all, especially preferably 400 or In addition, among the above-described acidic etching liquids, the acidic etching liquid that selectively etches the nitride film among the oxide film and the nitride film is an acidic etching liquid having an etching selectivity ratio [nitride film/oxide film] of, for example, 150 or greater (preferably 200 or greater, particularly preferably 250 or greater, most preferably 300 or greater, and above all, preferably 400 or greater).

The method for bringing the acidic etching liquid into contact with the [protection film/surface layer/inorganic material] laminate is not particularly limited, and examples include the following methods.
[3] A method of immersing the [protection film/surface layer/inorganic material] laminate in an acidic etching liquid (that is, a dipping method)
[4] A method of applying an acidic etching liquid onto the protection film of the [protection film/surface layer/inorganic material] laminate (that is, a coating method)

In the dipping method [3], the immersion time is, for example, from 0.1 to 5 minutes, and preferably from 0.5 to 3 minutes. The immersion temperature (for example, the temperature of the acidic etching liquid during immersion) is, for example, from 20 to 30° C.

According to the dipping method [3], the usage amount of the acidic etching liquid can be suppressed, thereby providing an economical merit. Further, since the etching process can be speedily carried out, productivity is high.

In the coating method [4], examples of the method for applying the acidic etching liquid onto the protection film of the [protection film/surface layer/inorganic material] laminate include spin coating, stamping, dispensing, squeegeeing, spraying, and brush coating.

According to the coating method [4], contamination of the inorganic material via the acidic etching liquid can be suppressed.

The etching selectivity ratio of the oxide film or the nitride film to the other of the oxide film and the nitride film in the method according to an embodiment of the present disclosure is, for example, 150 or greater, preferably 200 or greater, particularly preferably 250 or greater, most preferably 300 or greater, particularly preferably 400 or greater. Note that the etching selectivity ratio is a ratio between the etching rate of the oxide film and the etching rate of the nitride film, and is an etching selectivity ratio of [oxide film/nitride film] or an etching selectivity ratio of [nitride film/oxide film].

Note that the etching selectivity ratio [oxide film/nitride film] is the [etching rate of the oxide film]/[etching rate of the nitride film], and the etching selectivity ratio [nitride film/oxide film] is the [etching rate of nitride film]/[etching rate of oxide film].

The etching selectivity ratio [oxide film/nitride film] is, for example, 150 or greater, more preferably 160 or greater, still more preferably 170 or greater, even more preferably 200 or greater, yet even more preferably 250 or greater, particularly preferably 300 or greater, and most preferably 350 or greater.

In the method according to an embodiment of the present disclosure, the etching rate of the film to be etched among the oxide film and the nitride film is, for example, 85% or greater, preferably 90% or greater, more preferably 95% or greater, particularly preferably 98% or greater, and most preferably 99% or greater, of the etching rate under the same conditions without the provision of the protection film. That is, the reduction in the etching rate by the protection film is, for example, 15% or less, preferably 10% or less, more preferably 5% or less, particularly preferably 2% or less, and most preferably 1% or less.

In the method according to an embodiment of the present disclosure, the etching rate of the film not to be etched among the oxide film and the nitride film is, for example, 0.35 nm/min or less, preferably 0.3 nm/min or less, particularly preferably 0.25 nm/min or less, and most preferably 0.2 nm/min or less.

In the method according to an embodiment of the present disclosure, the etching rate of the oxide film when an acidic etching liquid that selectively etches the oxide film is used is, for example, 85% or greater, preferably 90% or greater, more preferably 95% or greater, particularly preferably 98% or greater, and most preferably 99% or greater, of the etching rate of the oxide film under the same conditions without the provision of the protection film. That is, the reduction in the etching rate by the protection film is, for example, 15% or less, preferably 10% or less, more preferably 5% or less, particularly preferably 2% or less, and most preferably 1% or less.

In the method according to an embodiment of the present disclosure, the etching rate of the nitride film when an acidic etching liquid that selectively etches the oxide film is used is, for example, 0.35 nm/min or less, preferably 0.3 nm/min or less, particularly preferably 0.25 nm/min or less, and most preferably 0.2 nm/min or less.

### Step 3

In step 3, the protection film remaining after the etching process of step 2 is washed and removed with warm water or an alkaline aqueous solution.

After the etching process, the protection film remains on, of the oxide film and the nitride film, the surface of the film that was not subjected to the etching process, even after the etching process. In this process, the remaining protection film is removed.

The remaining protection film can be easily removed by washing with warm water or an alkaline aqueous solution.

The warm water is, for example, water having a temperature of 40° C. or greater. The temperature of the warm water is preferably from 40 to 85° C., and the pH of the warm water is, for example, from 6 to 8, and preferably from 6.5 to 7.5. As the warm water, ultrapure water of having a temperature of 40° C. or greater is preferable.

The alkaline aqueous solution is, for example, an aqueous solution having a pH of 8 or greater. The pH of the alkaline aqueous solution is preferably 10 or greater, and particularly preferably 12 or greater. The temperature of the alkaline aqueous solution is, for example, less than 40° C., preferably 10° C. or higher and less than 40° C., and particularly preferably from 20 to 30° C.

The remaining protection film can be easily removed by washing with warm water or an alkaline aqueous solution, and damage to the etched surface layer when the protection film is removed can be prevented.

### Method for Manufacturing Semiconductor Device

A method for manufacturing a semiconductor device according to an embodiment of the present disclosure includes etching a surface layer of a semiconductor wafer having the surface layer including an oxide film and a nitride film by the above-described method for producing an inorganic material having an etched surface layer.

A semiconductor wafer having a surface layer including an oxide film and a nitride film can be manufactured by subjecting a semiconductor wafer to a film forming process such as thermal oxidation, chemical vapor deposition (CVD), and physical vapor deposition (PVD).

When a semiconductor wafer having a surface layer including an oxide film and a nitride film is subjected to the above-described method for producing an inorganic material having an etched surface layer, a semiconductor wafer in which the oxide film or the nitride film included in the surface layer is selectively etched is produced. Subsequently, a semiconductor element is produced through an electrode forming process, a dicing process, and the like, and the produced semiconductor element is further subjected to typically known semiconductor device manufacturing processes such as a wire bonding and molding, and thereby a semiconductor device can be manufactured.

The semiconductor device produced by the method according to an embodiment of the present disclosure includes a semiconductor element (for example, a semiconductor chip) having a high precision wiring pattern formed by extremely selective etching according to the etching process described above, and therefore the semiconductor device exhibits excellent reliability.

Examples of the semiconductor device include an integrated circuit such as an IC or an LSI; a light-emitting device such as a laser or an LED; a light-receiving device such as a solar cell, an optical sensor or a CMOS image sensor; a semiconductor sensor such as a MEMS; a memory, an analog IC, and a transistor.

The configurations and their combinations of the present disclosure described above are merely examples, and addition, omission, substitution, and modification of the configurations may be appropriately made without departing from the gist of the present disclosure. In addition, the present disclosure is not limited by the embodiments and is limited only by the claims.

### EXAMPLES

The present disclosure will next be described in more detail by way of Examples, but the present disclosure is not limited to the Examples.

The water-soluble polymer compounds and inorganic materials used in the Examples and Comparative Examples are as described below.

### Water-Soluble Polymer Compounds

HEC50: hydroxyethyl cellulose (degree of etherification: from 1.2 to 1.4, degree of crosslinking: 0.1%, weight-average molecular weight: 50×10⁴)
HEC25: hydroxyethyl cellulose (degree of etherification: from 1.2 to 1.4, degree of crosslinking: 0.1%, weight-average molecular weight: 25×10⁴)
HEC10: hydroxyethyl cellulose (degree of etherification: from 1.2 to 1.4, degree of crosslinking: 0.1%, weight-average molecular weight: 10×10⁴)
HEC6: hydroxyethyl cellulose (degree of etherification: from 1.2 to 1.4, degree of crosslinking: 0.25%, weight-average molecular weight: 6×10⁴)
HEC4: hydroxyethyl cellulose (degree of etherification: from 1.2 to 1.4, degree of crosslinking: 0.001%, weight-average molecular weight: 4×10⁴)
HEC2: hydroxyethyl cellulose (degree of etherification: from 1.2 to 1.4, degree of crosslinking: 0.02%, weight-average molecular weight: 2×10⁴)
HEC1: hydroxyethyl cellulose (degree of etherification: from 1.2 to 1.4, degree of crosslinking: 0.001%, weight-average molecular weight: 1×10⁴)
PGL: polyglycerin (trade name “PGL XPW”, available from Daicel Corporation)
PEG1000: polyethylene glycol (trade name “PEG #1000”, available from NOF Corporation)
PEG4000: polyethylene glycol (trade name “PEG #4000”, available from NOF Corporation)
PEG6000: polyethylene glycol (trade name “PEG #6000”, available from NOF Corporation)
PVA: polyvinyl alcohol (trade name “Gohsenol KL-05”, available from The Nippon Synthetic Chemical Industry Co., Ltd.)
PVP: polyvinylpyrrolidone (trade name “polyvinylpyrrolidone K-30”, available from Nippon Shokubai Co., Ltd.)

### Inorganic Material Including Oxide Film or Nitride Film

Th—SiO₂: silicon substrate with a 1.5 μm thick SiO₂ film formed by thermal oxidation, trade name “Th—SiO₂”, available from Advantec Co., Ltd.
LP-SiO₂: silicon substrate with a 200 nm thick SiO₂ film formed by LP-CVD, trade name “LP-SiO₂”, available from Advantec Co., Ltd.
LP-SiN: silicon substrate with a 200 nm thick Si₃N₄ film formed by LP-CVD, trade name “LP-SiN”, available from Advantec Co., Ltd.
PE-SiN: silicon substrate with a 300 nm thick Si₃N₄ film formed by PE-CVD, trade name “PE-SiN”, available from Advantec Co., Ltd.

The thickness of the protection film was measured with a spectroscopic ellipsometer (trade name “FE-5000”, available from Otsuka Electronics Co., Ltd.).

### Preparation Example 1

A protection film-forming solution (hereinafter, may be referred to as the “protection film-forming solution (HEC25:0.2 wt. %)”) was prepared by blending 0.2 g of HEC25 into 100 g of ultrapure water, and then stirring the mixture overnight in a ball-mill.

### Comparative Preparation Examples 1 to 6

Protection film-forming solutions were prepared in the same manner as in Preparation Example 1 with the exception of using PGL, PEG1000, PEG4000, PEG6000, PVA, or PVP instead of HEC25.

The adhesion of the protection film-forming solutions prepared in the Preparation Example and the Comparative Preparation Examples was evaluated by the following method.

### Adhesion Evaluation Method

The adhesion of each protection film-forming solution to an SiO₂ film or an Si₃N₄ film was evaluated by a quartz crystal microbalance (QCM) method using a QCM-D measuring device (trade name “QSense Explorer”, available from Biolin Scientific AB).

Ultrapure water was passed at a rate of 100 μL/s through a sensor (trade name “QSX303”, available from Biolin Scientific AB) having a film of SiO₂ formed on a quartz vibrator having a reference vibration frequency of 5 MHz or through a sensor (trade name “QSX328”, available from Biolin Scientific AB) having a film of Si₃N₄ formed on a quartz vibrator having a reference vibration frequency of 5 MHz until the frequency was stabilized, and then the protection film-forming solution was passed through the sensor for 900 seconds. Subsequently, ultrapure water was passed through the sensor for 600 seconds to wash away non-adhering components.

Adhesion was then evaluated based on the following criteria from a frequency change amount (harmonic number of 3) calculated by subtracting the frequency of the sensor before the above-described treatment from the frequency of the sensor after the above-described treatment.

Note that as the amount of water-soluble polymer compounds adhered to the sensor surface increased, the sensor became heavier and the frequency decreased.

### Adhesion Evaluation Criteria

∘ (good adhesion): The amount of change in the frequency was −5 Hz or less.
x (poor adhesion): The amount of change in the frequency was greater than −5 Hz and less than or equal to 0 Hz.

The results of the above evaluation are presented in Table 1.

TABLE 1

| | Preparation | Comparative Preparation Example | | | | | |
|---|---|---|---|---|---|---|---|
| | Example 1 | 1 | 2 | 3 | 4 | 5 | 6 |
| Water-soluble polymer | HEC25 | PGL | PEG1000 | PEG4000 | PEG6000 | PVA | PVP |
| compound | | | | | | | |
| Water-soluble polymer | 0.2 | 0.2 | 0.2 | 0.2 | 0.2 | 0.2 | 0.2 |
| compound concentration | | | | | | | |
| (wt. %) | | | | | | | |
| Adhesion | SiO₂ | ∘ | x | x | x | x | x |
| | Si₃N₄ | ∘ | x | x | x | x | x |

From Table 1, it was found that when a protection film-forming solution containing a water-soluble cellulose as a water-soluble polymer compound is used, the water-soluble cellulose adheres to the surfaces of the oxide film and the nitride film to form a protection film.

On the other hand, it was found that when the protection film-forming solutions containing PGL, PEG1000, PEG4000, PEG6000, PVA, or PVP as the water-soluble polymer compound are used, the water-soluble polymer compound does not easily adhere to the surfaces of the oxide film and the nitride film, and a protection film is not formed.

### Example 1

The protection film-forming solution (HEC25:0.2 wt. %) prepared in the Preparation Example was spin-coated onto LP-SiO₂ or LP-SiN as an inorganic material using a spin coater (available from Mikasa Co., Ltd.), and then heated on a hotplate at 150° C. for 90 seconds. Thereby, a protection film having a thickness of 15 nm was formed on the surface of the inorganic material.

The removability of the formed protection film was evaluated by the following method.

The following cleaning solution was dripped onto the protection film of the inorganic material and allowed to stand for 3 minutes, after which the cleaning solution was removed by air blowing. The presence or absence of the protection film was then confirmed visually or by using an infrared spectrometer (trade name “Spectrum One”, available from Perkin Elmer, Inc.) to evaluate the removability.

### Removability Evaluation Criteria

∘ (good removability): No protection film remaining
x (poor removability): Protection film is present.

### Cleaning Solutions

Ultrapure water (40° C., pH 7)
Ultrapure water (60° C., pH 7)
Ultrapure water (80° C., pH 7)
Aqueous potassium hydroxide solution (25° C., pH 12)
Ultrapure water (25° C., pH 7)
Aqueous hydrochloric acid solution (25° C., pH 1)
Isopropyl alcohol (IPA)

The results are presented in Table 2.

TABLE 2

| | | | | | KOH | | HCl | |
|---|---|---|---|---|---|---|---|---|
| | | Ultrapure | Ultrapure | Ultrapure | aqueous | Ultrapure | aqueous | |
| | | water | water | water | solution | water | solution | |
| | | 40° C. × | 60° C. × | 80° C. × | 25° C. × | 25° C. × | 25° C. × | |
| Cleaning Solution | | pH 7 | pH 7 | pH 7 | pH 12 | pH 7 | pH 1 | IPA |
| Removability | SiO₂ | ∘ | ∘ | ∘ | ∘ | x | x | x |
| | Si₃N₄ | ∘ | ∘ | ∘ | ∘ | x | x | x |

The results in Table 2 shows that the protection film containing the water-soluble cellulose and formed on the surfaces of the SiO₂ film and the Si₃N₄ film is removed by washing with warm water having a temperature of 40° C. or greater or with an alkaline aqueous solution, but is not removed by washing with water having a temperature of less than 40° C., or with an aqueous hydrochloric acid solution or IPA.

### Example 2

The protection film-forming solution (HEC25:0.2 wt. %) prepared in the Preparation Example was spin-coated onto Th—SiO₂ and LP-SiN as inorganic materials, and then heated on a hotplate at 150° C. for 90 seconds to form protection films having a thickness of 15 nm on the surfaces of the inorganic materials. Thereby, Th—SiO₂ with a protection film and LP-SiN with a protection film were produced.

The Th—SiO₂ with the protection film and the LP-SiN with the protection film were each subjected to an etching process in which the samples were immersed in an 85% phosphoric acid aqueous solution at 150° C. for etching times of 180 minutes and 30 minutes, respectively.

After the etching process, the thicknesses of the protection films were measured. Furthermore, a value calculated by dividing the film thickness (nm) reduced by the etching process by the etching time was defined as the etching rate (nm/min) of the Th—SiO₂ and LP-SiN.

The etching selectivity was then evaluated by calculating the selectivity ratio of [Si₃N₄/SiO₂] from the ratio between the etching rate of the LP-SiN and the etching rate of the Th—SiO₂.

### Comparative Example 1

The etching rates and the [Si₃N₄/SiO₂] selectivity ratio were calculated in the same manner as in Example 2 with the exception that the protection film-forming solution was not used.

### Comparative Examples 2 to 5

The etching rates and the [Si₃N₄/SiO₂] selectivity ratio were calculated in the same manner as in Example 2 with the exception that protection film-forming solutions containing the water-soluble polymer compounds shown in the following table at the concentrations described in the following table were used instead of the protection film-forming solution (HEC25:0.2 wt. %).

The abovementioned results are presented in Table 3.

TABLE 3

| | | Example | Comparative Examples | | | | |
|---|---|---|---|---|---|---|---|
| | | 2 | 1 | 2 | 3 | 4 | 5 |
| Water-soluble polymer compound | | HEC25 | — | PGL | PEG1000 | PVA | PVP |
| Water-soluble polymer compound | | 0.2 | 0.2 | 0.2 | 0.2 | 0.2 | 0.2 |
| concentration (wt. %) | | | | | | | |
| Etching rate | Th—SiO₂ | 0.008 | 0.013 | 0.014 | 0.011 | 0.013 | 0.010 |
| (nm/min) | LP-SiN | 3.18 | 3.32 | 3.28 | 3.23 | 3.52 | 3.43 |

| | | | | | | |
|---|---|---|---|---|---|---|
| Si₃N₄/SiO₂ selectivity ratio | 398 | 255 | 234 | 293 | 270 | 343 |

From Table 3 above, it was found that when the etching process is carried out using the protection film-forming solution containing a water-soluble cellulose as the water-soluble polymer compound and using an acidic etching liquid that selectively etches the nitride film, the etching rate of the oxide film is significantly reduced while suppressing a reduction in the etching rate of the nitride film as compared with the case of using the protection film-forming solution containing another water-soluble polymer compound, and therefore as a result, the [nitride film/oxide film] selectivity ratio is improved.

### Example 3

The protection film-forming solution (HEC25:0.2 wt. %) prepared in the Preparation Example was spin-coated onto Th—SiO₂, LP-SiO₂, and LP-SiN as inorganic materials, and then heated on a hotplate at 150° C. for 90 seconds to form protection films having a thickness of 15 nm on the surfaces of the inorganic materials. Thereby, Th—SiO₂ with a protection film, LP-SiO₂ with a protection film, and LP-SiN with a protection film were produced.

The surface of the protection film of the Th—SiO₂ with the protection film was subjected to an etching treatment in which three drops of buffered hydrofluoric acid (trade name “BHF110”, available from Daikin Industries, Ltd.) were dripped onto the protection film surface thereof and left to stand for 5 minutes, and the etching rate was then calculated.

The surface of the protection film of the LP-SiO₂ with the protection film was subjected to an etching treatment in which three drops of buffered hydrofluoric acid were dripped onto the protection film surface thereof and left to stand for 1 minute, and the etching rate was then calculated.

The surface of the protection film of the LP-SiN with the protection film was subjected to an etching treatment in which three drops of buffered hydrofluoric acid were dripped onto the protection film surface thereof and left to stand for 30 minutes, and the etching rate was then calculated.

Furthermore, as the [SiO₂/Si₃N₄] selectivity ratio, the ratio of the etching rate of Th—SiO₂ to the etching rate of LP-SiN and the ratio of the etching rate of LP-SiO₂ to the etching rate of LP-SiN were calculated.

### Comparative Example 6

The etching rates and the [SiO₂/Si₃N₄] selectivity ratio were calculated in the same manner as in Example 3 with the exception that the protection film-forming solution was not used.

### Comparative Examples 7 and 8

The etching rates and the [SiO₂/Si₃N₄] selectivity ratio were calculated in the same manner as in Example 3 with the exception that protection film-forming solutions containing the water-soluble polymer compounds shown in the following table at the concentrations described in the following table were used instead of the protection film-forming solution (HEC25:0.2 wt. %).

The abovementioned results are presented in Table 4.

TABLE 4

| | | | Water-soluble | | | | | |
|---|---|---|---|---|---|---|---|---|
| | | Water- | polymer | Etching rate | | | SiO₂/Si₃N₄ | |
| | | soluble | compound | (nm/min) | | | selectivity ratio | |
| | | polymer | concentration | | LP- | LP- | (Th—SiO₂)/ | (LP-SiO₂)/ |
| | | compound | (wt. %) | Th—SiO₂ | SiO₂ | SiN | (LP-SiN) | (LP-SiN) |
| Example | 3 | HEC25 | 0.2 | 42.6 | 110.1 | 0.22 | 194 | 500 |
| Comparative | 6 | — | 0.2 | 49.7 | 100.3 | 0.55 | 90 | 182 |
| Examples | 7 | PGL | 0.2 | 49.1 | 99.5 | 0.54 | 91 | 184 |
| | 8 | PEG1000 | 0.2 | 48.3 | 101.2 | 0.55 | 88 | 184 |

From Table 4 above, it was found that when the etching process is carried out using the protection film-forming solution containing a water-soluble cellulose as the water-soluble polymer compound and using an acidic etching liquid that selectively etches the oxide film, the etching rate of the nitride film is significantly reduced while suppressing a reduction in the etching rate of the oxide film as compared with the case of using the protection film-forming solution containing another water-soluble polymer compound, and therefore as a result, the [oxide film/nitride film] selectivity ratio is improved.

### Example 4

Th—SiO₂, LP-SiO₂, and LP-SiN were immersed as inorganic materials into the protection film-forming solution (HEC25:0.2 wt. %) prepared in the Preparation Example for 3 minutes, and then immersed in ultrapure water for 3 minutes.

Subsequently, the inorganic materials were not subjected to a drying treatment, and only the excess water was removed.

The etching rates and the [SiO₂/Si₃N₄] selectivity ratios were calculated in the same manner as in Example 3 with the exception that buffered hydrofluoric acid was dripped onto the Th—SiO₂, the LP-SiO₂ and the LP-SiN thus produced.

### Comparative Example 9

The etching rates and the [SiO₂/Si₃N₄] selectivity ratio were calculated in the same manner as in Example 4 with the exception that the protection film-forming solution was not used.

### Comparative Examples 10 and 11

The etching rates and the [SiO₂/Si₃N₄] selectivity ratio were calculated in the same manner as in Example 4 with the exception that protection film-forming solutions containing the water-soluble polymer compounds shown in the following table at the concentrations described in the following table were used instead of the protection film-forming solution (HEC25:0.2 wt. %).

The abovementioned results are presented in Table 5.

TABLE 5

| | | | Water-soluble | | | | | |
|---|---|---|---|---|---|---|---|---|
| | | Water- | polymer | Etching rate | | | SiO₂/Si₃N₄ | |
| | | soluble | compound | (nm/min) | | | selectivity ratio | |
| | | polymer | concentration | | LP- | LP- | (Th—SiO₂)/ | (LP-SiO₂)/ |
| | | compound | (wt. %) | Th—SiO₂ | SiO₂ | SiN | (LP-SiN) | (LP-SiN) |
| Example | 4 | HEC25 | 0.2 | 51.7 | 148.2 | 0.46 | 112 | 322 |
| Comparative | 9 | — | 0.2 | 51.8 | 131.5 | 0.61 | 85 | 216 |
| Examples | 10 | PGL | 0.2 | 52.1 | 130.3 | 0.61 | 85 | 214 |
| | 11 | PEG1000 | 0.2 | 51.5 | 130.2 | 0.59 | 87 | 221 |

From Table 4 and Table 5, it was found that the protection film-forming solution containing the water-soluble cellulose exhibits an effect of improving the etching selectivity by merely being applied to the surface of the inorganic material, and that when the protection film-forming solution is applied to the surface of the inorganic material and then dried, a more excellent effect of improving the etching selectivity is exhibited.

### Example 11A

### Protection Film Preparation and Heated Drying

The protection film-forming solution (HEC25:0.2 wt. %)) prepared in the Preparation Example was spin coated onto a silicon substrate having an SiO₂ film (Th—SiO₂), and then heated on a hotplate at 150° C. for 90 seconds, and a [protection film/SiO₂ film/silicon substrate] laminate 1a having a protection film with a thickness of 15 nm on the substrate surface was produced.

### Etching Process

Three drops of buffered hydrofluoric acid (trade name “BHF110”, available from Daikin Industries, Ltd.) were dripped onto the surface of the protection film of the [protection film/SiO₂ film/silicon substrate] laminate 1a and left to stand for 5 minutes. Thereby, an etched laminate 1a′ was produced, and the etching rate was calculated.

### Removal of Remaining Protection Film

After the etching process, the following cleaning solution was dripped onto the laminate 1a′ and left to stand for 3 minutes, after which the moisture was removed by air blowing to produce a laminate 1a″. When the presence or absence of the protection film remaining on the laminate 1a″ was visually confirmed, no residual material was observed in cases using any of the cleaning solutions.

### Cleaning Solutions

Ultrapure water (40° C., pH 7)
Ultrapure water (60° C., pH 7)
Ultrapure water (80° C., pH 7)
Aqueous potassium hydroxide solution (25° C., pH 12)

Note that it was confirmed that the protection film remaining on the laminate 1a″ was not removed even when washed with 25° C. ultrapure water (pH 7) or a 25° C. aqueous hydrochloric acid solution (pH 1).

From this, it is clear that the protection film is not removed in the process of etching using an acidic etching liquid, and a state in which the protection film covers the surface layer of the inorganic material is maintained.

### Example 11B

### Protection Film Preparation and Drying

A [protection film/Si₃N₄ film/silicon substrate] laminate 1b having a protection film with a thickness 15 nm on the substrate surface was produced in the same manner as in Example 11A with the exception that a silicon substrate having a Si₃N₄ film (LP-SiN) was used instead of the silicon substrate with the SiO₂ film (Th—SiO₂).

### Etching Process

Three drops of buffered hydrofluoric acid (trade name “BHF110”, available from Daikin Industries, Ltd.) were dripped onto the surface of the protection film of the [protection film/Si₃N₄ film/silicon substrate] laminate 1b, and the laminate was left to stand for 30 minutes. Thereby, an etched laminate 1b′ was produced and the etching rate was calculated.

The [SiO₂/Si₃N₄] selectivity ratio was calculated from the results of Example 11A and Example 11B.

### Comparative Example 21

An etched laminate was produced in the same manner as in Examples 11A and 11B with the exception that the silicon substrate with the SiO₂ film (Th—SiO₂) or the silicon substrate with the Si₃N₄ film (LP-SiN) was etched without preparing the protection film, and then the etching rates and the [SiO₂/Si₃N₄] selectivity ratio were calculated.

### Comparative Examples 22 and 23

Etched laminates were produced in the same manner as in Examples 11A and 11B with the exception that protection film-forming solutions containing the water-soluble polymer compounds shown in the following table at the concentrations described in the following table were used in the protection film preparation and drying processes instead of the protection film-forming solution (HEC25:0.2 wt. %), and the etching rates and the [SiO₂/Si₃N₄] selectivity ratios were calculated.

The results are summarized and shown in the following table.

TABLE 6

| | | Compar- | Compar- | Compar- |
|---|---|---|---|---|
| | | ative | ative | ative |
| | Exam- | Exam- | Exam- | Exam- |
| | ple 11 | ple 21 | ple 22 | ple 23 |
| Water-soluble | HEC25 | — | PGL | PEG1000 |
| polymer compound | | | | |
| Water-soluble | 0.2 | — | 0.2 | 0.2 |
| polymer compound | | | | |
| concentration (wt. %) | | | | |
| SiO₂ etching rate (nm/min) | 42.6 | 49.7 | 49.1 | 48.3 |
| Si₃N₄ etching rate (nm/min) | 0.22 | 0.55 | 0.54 | 0.55 |
| [SiO₂/Si₃N₄] | 194 | 90 | 91 | 88 |
| selectivity ratio | | | | |

From Table 6, it is clear that when treated with an acidic etching liquid that selectively etches the oxide film, the protection film containing the water-soluble cellulose significantly suppresses etching of the nitride film while maintaining etching of the oxide film, and thereby improves the etching selectivity.

### Example 12A

### Protection Film Preparation

A silicon substrate with a Si₃N₄ film was immersed in a protection film-forming solution (HEC25:0.5 wt. %) for 3 minutes to produce a [protection film/Si₃N₄ film/silicon substrate] laminate.

Washing with Water

The produced [protection film/Si₃N₄ film/silicon substrate] laminate was washed with ultrapure water for 3 minutes.

### Etching Process

Excess water was removed from the produced [protection film/Si₃N₄ film/silicon substrate] laminate, and with the protection film still containing moisture, the laminate was immersed in buffered hydrofluoric acid (trade name “BHF110”, available from Daikin Industries, Ltd.) for 30 minutes. Thereby, an etched laminate was produced, and the etching rate was then calculated.

### Example 12B

An etched laminate was produced in the same manner as in Example 12A with the exception that a silicon substrate plate with a SiO₂ film (Th—SiO₂) was used instead of the silicon substrate with the Si₃N₄ film (LP-SiN), and the immersion time in buffered hydrofluoric acid (trade name “BHF110”, available from Daikin Industries, Ltd.) was changed from 30 minutes to 10 minutes, and the etching rate was calculated.

The [SiO₂/Si₃N₄] selectivity ratio was calculated from the results of Example 12A and Example 12B.

### Example 13A

### Protection Film Preparation

A silicon substrate with a Si₃N₄ film was immersed in a protection film-forming solution (HEC25:0.5 wt. %) for 3 minutes to produce a [protection film/Si₃N₄ film/silicon substrate] laminate.

Washing with Water

The produced [protection film/Si₃N₄ film/silicon substrate] laminate was washed with ultrapure water for 3 minutes.

### Drying

After washing with water, excess water adhered to the [protection film/Si₃N₄ film/silicon substrate] laminate was removed, and the laminate was blown with dry nitrogen gas to remove the moisture contained in the protection film. The moisture content of the protection film after the drying treatment was 5 wt. % or less.

### Etching Process

The dried [protection film/Si₃N₄ film/silicon substrate] laminate was immersed in buffered hydrofluoric acid (trade name “BHF110”, available from Daikin Industries, Ltd.) for 30 minutes. Thereby, an etched laminate was produced, and the etching rate was then calculated.

### Example 13B

An etched laminate was produced in the same manner as in Example 13A with the exception that a silicon substrate plate with a SiO₂ film (Th—SiO₂) was used instead of the silicon substrate with the Si₃N₄ film (LP-SiN), and the immersion time in buffered hydrofluoric acid (trade name “BHF110”, available from Daikin Industries, Ltd.) was changed from 30 minutes to 10 minutes, and the etching rate was calculated.

The [SiO₂/Si₃N₄] selectivity ratio was calculated from the results of Example 13A and Example 13B.

### Example 14A

An etched laminate was produced in the same manner as in Example 13A with the exception that a protection film-forming solution (HEC25:0.2 wt. %) was used instead of the protection film-forming solution (HEC25:0.5 wt. %), and the etching rate was calculated.

### Example 14B

An etched laminate was produced in the same manner as in Example 14A with the exception that a silicon substrate plate with a SiO₂ film (Th—SiO₂) was used instead of the silicon substrate with the Si₃N₄ film (LP-SiN), and the immersion time in buffered hydrofluoric acid (trade name “BHF110”, available from Daikin Industries, Ltd.) was changed from 30 minutes to 10 minutes, and the etching rate was calculated.

The [SiO₂/Si₃N₄] selectivity ratio was calculated from the results of Example 14A and Example 14B.

### Comparative Example 24

An etched laminate was produced in the same manner as in Examples 12A and 12B with the exception that the protection film preparation, the water washing treatment, and the drying treatment were not implemented, and then the etching rates and the [SiO₂/Si₃N₄] selectivity ratio were calculated.

### Comparative Example 25

An etched laminate was produced in the same manner as in Examples 12A and 12B with the exception that the protection film preparation and the drying treatment were not implemented, and then the etching rates and the [SiO₂/Si₃N₄] selectivity ratio were calculated.

### Comparative Examples 26 to 28

Etched laminates were produced in the same manner as in Examples 13A and 13B with the exception that protection film-forming solutions containing the water-soluble polymer compounds shown in the following table at the concentrations described in the following table were used in the protection film preparation instead of the protection film-forming solution (HEC25:0.5 wt. %), and the etching rates and the [SiO₂/Si₃N₄] selectivity ratios were calculated.

The results are summarized and shown in the following table.

TABLE 7

| | Example | Example | Example | Comparative | Comparative | Comparative | Comparative | Comparative |
|---|---|---|---|---|---|---|---|---|
| | 12 | 13 | 14 | Example 24 | Example 25 | Example 26 | Example 27 | Example 28 |
| Water-soluble polymer | HEC25 | HEC25 | HEC25 | — | — | PEG4000 | PVA | PVP |
| compound | | | | | | | | |
| Water-soluble polymer | 0.5 | 0.5 | 0.2 | — | — | 0.5 | 0.5 | 0.5 |
| compound concentration (wt. %) | | | | | | | | |
| Washing with water | ∘ | ∘ | ∘ | — | ∘ | ∘ | ∘ | ∘ |
| Drying | — | ∘ | ∘ | — | — | ∘ | ∘ | ∘ |
| SiO₂ etching rate (nm/min) | 57.4 | 57.8 | 57.8 | 57.8 | 57.8 | 56.5 | 57.6 | 58.7 |
| Si₃N₄ etching rate (nm/min) | 0.37 | 0.16 | 0.34 | 0.46 | 0.47 | 0.44 | 0.45 | 0.44 |
| [SiO₂/Si₃N₄] selectivity ratio | 155 | 361 | 170 | 126 | 123 | 128 | 128 | 133 |

Table 7 shows that when a protection film containing a water-soluble cellulose and having a reduced moisture content is formed on the surface layer of an inorganic material having the surface layer including an oxide film and a nitride film, and then the inorganic material is subjected to an etching process, the etching inhibition of the film to be etched among the oxide film and the nitride film can be reduced, and the etching inhibition of the film not to be etched can be increased, and thereby the etching selectivity is improved. In addition, it shows that when the concentration of the water-soluble cellulose contained in the protection film is increased, the abovementioned effect is further improved.

Table 6 and Table 7 show that according to the method of the present disclosure, when a protection film containing a water-soluble cellulose is provided on the surface layer of the inorganic material having the surface layer including the oxide film and the nitride film, the etching selectivity can be maintained at a high level even when the etching rate is increased by adjusting the etching process conditions.

### Example 15A

A silicon substrate with a PE-SiN film was immersed for 10 seconds in a protection film-forming solution containing a water-soluble polymer compound described in the following table at the concentration described in the following table, and thereby a [protection film/Si₃N₄ film/silicon substrate] laminate was produced.

Excess water was removed from the produced [protection film/Si₃N₄ film/silicon substrate] laminate, and with the protection film still containing moisture, the laminate was immersed in buffered hydrofluoric acid (trade name “BHF110”, available from Daikin Industries, Ltd.) for 5 minutes.

Thereby, an etched laminate was produced, and the etching rate was then calculated.

### Example 15B

An etched laminate was produced in the same manner as in Example 15A with the exception that a Th—SiO₂ film was used instead of the PE-SiN film, and the etching rate was calculated.

The [SiO₂/Si₃N₄] selectivity ratio was calculated from the results of Example 15A and Example 15B.

### Examples 16 to 21 and Comparative Example 29

Etched laminates were produced in the same manner as in Examples 15A and 15B with the exception that protection film-forming solutions containing the water-soluble polymer compounds shown in the following table at the concentrations described in the following table were used, and the etching rates and the [SiO₂/Si₃N₄] selectivity ratios were calculated.

The results are summarized and shown in the following table.

TABLE 8

| | Example | Example | Example | Example | Example | Example | Example | Comparative |
|---|---|---|---|---|---|---|---|---|
| | 15 | 16 | 17 | 18 | 19 | 20 | 21 | Example 29 |
| Water-soluble polymer | HEC1 | HEC2 | HEC4 | HEC6 | HEC10 | HEC25 | HEC50 | — |
| compound | | | | | | | | |
| Water-soluble polymer | 0.3 | 0.3 | 0.3 | 0.3 | 0.3 | 0.3 | 0.3 | — |
| compound concentration (wt. %) | | | | | | | | |
| Weight-average molecular | 10000 | 20000 | 40000 | 60000 | 100000 | 250000 | 500000 | — |
| weight | | | | | | | | |
| Crosslinking degree (%) | 0.001 | 0.02 | 0.001 | 0.25 | 0.1 | 0.1 | 0.1 | — |
| SiO₂ etching rate (nm/min) | 59.4 | 59.4 | 59.7 | 59.2 | 58.5 | 58.3 | 58.1 | 60 |
| SiN etching rate (nm/m) | 3.7 | 3.7 | 3.8 | 6 | 3.9 | 6 | 13 | 17 |
| [SiO₂/Si₃N₄] selectivity ratio | 16.1 | 16.1 | 15.7 | 9.9 | 15 | 9.7 | 4.5 | 3.5 |
| Color unevenness | None | None | None | Present | None | Present | Present | Present |

Table 8 shows that when a water-soluble polymer compound having a low weight-average molecular weight is used as the water-soluble polymer compound, the etching selectivity is improved, and the color unevenness of the substrate after etching is minimal.

In addition, it also shows that when a water-soluble polymer compound having a low degree of crosslinking is used as the water-soluble polymer compound, the etching selectivity is improved and the color unevenness of the substrate after etching is minimal.

To summarize the above, configurations and variations of the present disclosure are additionally described below.
[1] A surface layer protection film for an inorganic material, the surface layer protection film containing a water-soluble cellulose.
[2] The surface layer protection film according to [1], in which the water-soluble cellulose is a cellulose derivative having a constituent unit represented by Formula (c) or a salt thereof.
[3] An etching method for an inorganic material, the inorganic material including, on a surface layer thereof, two types of films having different etching rates when etched with an acidic etching liquid, the etching method including selectively etching, of two types of films, the film having the higher etching rate, by.
(A) simultaneously supplying an aqueous solution containing a water-soluble cellulose and an acidic etching liquid to the surface layer; or
(B) supplying an aqueous solution containing a water-soluble cellulose to the surface layer, and then supplying an acidic etching liquid to the surface layer.
[4] A method for producing an inorganic material having an etched surface layer, the method including subjecting an inorganic material having a surface layer including an oxide film and a nitride film to steps 1 and 2 to produce the inorganic material having the etched surface layer, wherein the steps 1 and 2 are:
1: producing a [protection film/surface layer/inorganic material] laminate by laminating the surface layer protection film described in [1] or [2] to the surface layer of the inorganic material having a surface layer including an oxide film and a nitride film; and
2: selectively etching the oxide film or the nitride film of the surface layer by bringing an acidic etching liquid that selectively etches the oxide film or the nitride film into contact with the [protection film/surface layer/inorganic material] laminate.
[5] The method for producing an inorganic material having an etched surface layer according to [4], in which, in the step 2, an etching selectivity ratio of the oxide film or the nitride film in relation to the other of the oxide film or the nitride film in the selectively etching is 150 or greater.
[6] The production method according to [4] or [5], in which, in the step 1, the surface layer protection film is laminated by applying an aqueous solution containing a water-soluble cellulose to the surface layer of the inorganic material having a surface layer including an oxide film and a nitride film, and then drying the aqueous solution and the surface layer.
[7] The production method according to any one of [4] to [6], in which the steps 1 and 2 are followed by:
3: washing and removing the remaining protection film with warm water or an alkaline aqueous solution.

[8] A method for manufacturing a semiconductor device, the manufacturing method including etching, by the production method described in any one of [4] to
[7], a surface layer of a semiconductor wafer having a surface layer including an oxide film and a nitride film.
[9] An inorganic material provided with a surface layer protection film containing a water-soluble cellulose.
[10] A laminate including:
an inorganic material; and
a surface layer protection film containing a water-soluble cellulose,
in which
the surface layer protection film is laminated on a surface of the inorganic material.
[11] A laminate including:
an inorganic material having a surface layer including an oxide film and a nitride film; and a surface layer protection film containing a water-soluble cellulose,
in which
the surface layer protection film is laminated on the surface layer of the inorganic material.
[12] A laminate including:
a silicon substrate having a surface layer including a silicon oxide film and a silicon nitride film; and
a surface layer protection film containing a water-soluble cellulose,
in which
the surface layer protection film is laminated on the surface layer of the silicon substrate.

### INDUSTRIAL APPLICABILITY

The protection film of the present disclosure adheres well to a surface layer of an inorganic material during an etching process in which an acidic etching liquid is used, and exhibits an effect of improving etching selectivity. Furthermore, the protection film can be easily removed by washing with warm water or an alkaline aqueous solution.

When the protection film is used, an inorganic material having a surface layer that is etched with high precision can be produced, and a high-performance semiconductor device can be manufactured.

1. A surface layer protection film for an inorganic material, the surface layer protection film comprising a water-soluble cellulose.

2. The surface layer protection film according to claim 1, wherein the water-soluble cellulose is a cellulose derivative having a constituent unit represented by Formula (c) or a salt thereof: 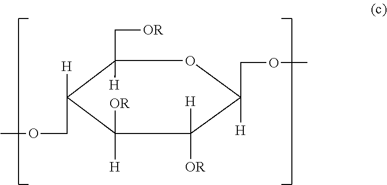
where three R's may be the same or different, and each denotes a hydrogen atom, a hydrocarbon group, or a group in which two or more hydrocarbon groups are bonded through a linking group, and the hydrocarbon group may have a hydroxyl group or a carboxyl group, with proviso that at least one of three R's is a hydrocarbon group or a group in which two or more hydrocarbon groups are bonded through a linking group.

3. An etching method for an inorganic material, the inorganic material comprising, on a surface layer thereof, two types of films having different etching rates when etched with an acidic etching liquid, the etching method comprising selectively etching, of the two types of films, the film having the higher etching rate, by:
(A) simultaneously supplying an aqueous solution containing a water-soluble cellulose and an acidic etching liquid to the surface layer; or
(B) supplying an aqueous solution containing a water-soluble cellulose to the surface layer, and then supplying an acidic etching liquid to the surface layer.

4. A method for producing an inorganic material having an etched surface layer, the method comprising subjecting an inorganic material having a surface layer including an oxide film and a nitride film to steps 1 and 2 to produce the inorganic material having the etched surface layer, wherein the steps 1 and 2 are:
1: producing a protection film/surface layer/inorganic material laminate by laminating the surface layer protection film described in claim 1 to the surface layer of the inorganic material having a surface layer including an oxide film and a nitride film; and
2: selectively etching the oxide film or the nitride film of the surface layer by bringing an acidic etching liquid that selectively etches the oxide film or the nitride film into contact with the protection film/surface layer/inorganic material laminate.

5. The method for producing an inorganic material having an etched surface layer according to claim 4, wherein, in the step 2, an etching selectivity ratio of the oxide film or the nitride film in relation to the other of the oxide film and the nitride film in the selectively etching is 150 or greater.

6. The method for producing an inorganic material having an etched surface layer according to claim 4, wherein in the step 1, the surface layer protection film is laminated by applying an aqueous solution containing a water-soluble cellulose to the surface layer of the inorganic material having a surface layer including an oxide film and a nitride film, and then drying the aqueous solution and the surface layer.

7. The method for producing an inorganic material having an etched surface layer according to claim 4, wherein the steps 1 and 2 are followed by:
3: washing and removing the remaining protection film with warm water or an alkaline aqueous solution.

8. A method for manufacturing a semiconductor device, the manufacturing method comprising etching a surface layer of a semiconductor wafer having a surface layer including an oxide film and a nitride film by the method for producing an inorganic material having an etched surface layer described in claim 4.

9. The surface layer protection film according to claim 1, wherein a weight-average molecular weight of the water-soluble cellulose is from 0.5×10⁴ to 30×10⁴.

10. The surface layer protection film according to claim 1, wherein a degree of crosslinking of the water-soluble cellulose is 0.3% or less.

11. The surface layer protection film according to claim 1, wherein the water-soluble cellulose is at least one compound selected from the group consisting of hydroxyethyl cellulose, hydroxypropyl cellulose, hydroxyethylmethyl cellulose, and hydroxypropylmethyl cellulose.

12. The surface layer protection film according to claim 1, wherein the water-soluble cellulose is at least one compound selected from the group consisting of hydroxyethyl cellulose, hydroxypropyl cellulose, hydroxyethylmethyl cellulose, and hydroxypropylmethyl cellulose, and a total degree of substitution of a hydroxyethyl group or a hydroxypropyl group of the at least one compound is from 1.0 to 2.0.

13. The surface layer protection film according to claim 1, wherein the water-soluble cellulose is at least one compound selected from the group consisting of hydroxyethyl cellulose, hydroxypropyl cellulose, hydroxyethylmethyl cellulose, and hydroxypropylmethyl cellulose, and a weight-average molecular weight of the at least one compound is from 0.5×10⁴ to 30×10⁴.

14. The surface layer protection film according to claim 1, wherein the water-soluble cellulose is at least one compound selected from the group consisting of hydroxyethyl cellulose, hydroxypropyl cellulose, hydroxyethylmethyl cellulose, and hydroxypropylmethyl cellulose, and a degree of crosslinking of the at least one compound is 0.3% or less.

15. A method for producing an inorganic material having an etched surface layer, the method comprising subjecting an inorganic material having a surface layer including an oxide film and a nitride film to steps 1 and 2 to produce the inorganic material having the etched surface layer, wherein the steps 1 and 2 are:
1: producing a [protection film/surface layer/inorganic material] laminate by applying an aqueous solution containing a water-soluble cellulose to the surface layer of the inorganic material having a surface layer including an oxide film and a nitride film, and then drying the aqueous solution and the surface layer; and
2: selectively etching the oxide film or the nitride film of the surface layer by bringing an acidic etching liquid that selectively etches the oxide film or the nitride film into contact with the [protection film/surface layer/inorganic material] laminate.

16. The method for producing an inorganic material according to claim 15, wherein a weight-average molecular weight of the water-soluble cellulose is from 0.5×10⁴ to 30×10⁴.

17. The method for producing an inorganic material according to claim 15, wherein a degree of crosslinking of the water-soluble cellulose is 0.3% or less.

18. The method for producing an inorganic material according to claim 15, wherein the water-soluble cellulose is at least one compound selected from the group consisting of hydroxyethyl cellulose, hydroxypropyl cellulose, hydroxyethylmethyl cellulose, and hydroxypropylmethyl cellulose.

19. The method for producing an inorganic material according to claim 15, wherein the water-soluble cellulose is at least one compound selected from the group consisting of hydroxyethyl cellulose, hydroxypropyl cellulose, hydroxyethylmethyl cellulose, and hydroxypropylmethyl cellulose, and a total degree of substitution of a hydroxyethyl group or a hydroxypropyl group of the at least one compound is from 1.0 to 2.0.

20. The method for producing an inorganic material according to claim 15, wherein the water-soluble cellulose is at least one compound selected from the group consisting of hydroxyethyl cellulose, hydroxypropyl cellulose, hydroxyethylmethyl cellulose, and hydroxypropylmethyl cellulose, and a degree of crosslinking of the at least one compound is 0.3% or less.
